(19) United States
(12) Patent Application Publication
(10) Pub. No.: US 2025/0063955 A1
(43) Pub. Date: Feb. 20, 2025

(54) Memory and Method for Manufacturing Thereof

(71) Applicant: ZHEJIANG HIKSTOR TECHNOLOGY CO., LTD, Hangzhou, Zhejiang (CN)

(72) Inventors: Zhimeng YU, Hangzhou, Zhejiang (CN); Shikun HE, Hangzhou, Zhejiang (CN)

(21) Appl. No.: 18/721,840

(22) PCT Filed: Dec. 6, 2022
(86) PCT No.: PCT/CN2022/136781

§ 371 Date: Jun. 19, 2024

(30) Foreign Application Priority Data
Mar. 4, 2022 (CN) 202210213392.4

(51) Int. Cl. H10N 70/00; H10B 61/00; H10B 63/00; H10N 50/01

(52) U.S. Cl. CPC H10N 70/063; H10B 61/10; H10B 63/80; H10N 50/01

(57) ABSTRACT

Disclosed in the present application are a memory and a method for manufacturing thereof. The manufacturing method includes: bottom electrodes of a memory array region and a first portion of top contact body of a logic region are formed on an upper surface of a bottom circuit layer simultaneously; a patterned dielectric layer is formed on an upper surface of a memory cell layer in the memory array region and the logic region; hard masks and a second portion of top contact body are formed in a via of the patterned dielectric layer simultaneously, where the hard masks corresponds to the bottom electrodes, and the second portion of top contact body is connected to the first portion of top contact body in a contact manner; and the memory cell layer is etched to form memory cells.

### CROSS-REFERENCE TO RELATED APPLICATION

The disclosure claims the priority and benefit of patent application No. 202210213392.4, filed with the China National Intellectual Property Administration on Mar. 4, 2022, which are incorporated in their entireties herein by reference.

### TECHNICAL FIELD

The present application relates to the field of semiconductors, in particular to a memory and a method for manufacturing thereof.

### BACKGROUND

A resistive memory such as a magnetic random access memory (MRAM), a resistive random access memory (RRAM), etc. can be divided into a memory array region for memory functions and a logic region for logic functions and other functions. Bottom electrodes in the memory array region needs to have a high aspect ratio to minimize re-deposition caused during etching of memory cell layers and to guarantee adequate cleaning after main etching, as well as avoiding metal contamination caused by patterning of the memory cells.

Current method to form the top contact body of the logic region is to conduct at least one lithography and one etch step after etching of the memory cell of the memory array region followed by backfilling of dielectric materials. That is, the preparation of logic top contact body is of complicated and costly.

Moreover, with the technology nodes scaling and trending to high density, more cleaning and over-etching is required after main etching of the memory cell. To guarantee the device performance taller bottom electrodes and corresponding taller logic top contact body are essential. Furthermore, the size of logic top contact body decreases together with the technology nodes as well. The above mentioned factors greatly increase the difficulty of filling logic top contact via to form the logic top contact body. Because of the process limitation of copper plating when filling high aspect ratio structures, there is a high risk on reliability issue.

Therefore, how to solve the above technical problems should be focused on by those skilled in the art.

### SUMMARY

An objective of the present application is to provide a memory and a method for manufacturing thereof.

The present application provides a method for manufacturing a memory. The method for manufacturing a memory includes:
bottom electrodes of a memory array region and a first portion of top contact body of a logic region are formed on an upper surface of a bottom circuit layer simultaneously;
a patterned dielectric layer is formed on an upper surface of a memory cell layer and the logic region;
hard masks and a second portion of top contact body are formed in vias of the patterned dielectric layer simultaneously, where the hard masks corresponds to the bottom electrodes, and the second portion of top contact body is connected to the first portion of top contact body in a contact manner; and
the memory cell layer is etched to form memory cells.

In some embodiments, before the memory cell layer being etched to form the memory cells, and after the patterned dielectric layer above a plane of the upper surface of the memory cell layer being removed, the method for manufacturing a memory further includes:

a dielectric layer is deposited in the memory array region and the logic region.

In some embodiments, a width of the via corresponding to the second portion of top contact body is less than a width of the first portion of top contact body when patterning the dielectric layer.

In some embodiments, once the memory cell layer is etched to form the memory cells, the method for manufacturing a memory further includes:

a protective layer is deposited in the memory array region and the logic region.

In some embodiments, a forming process of the memory cell layer in the memory array region includes:
the memory cell layer, a dielectric hard mask layer and a photoresist layer are sequentially stack in the memory array region and the logic region;
the photoresist layer in the logic region is removed;
the dielectric hard mask layer in the logic region and the photoresist layer in the memory array region are removed; and
the memory cell layer in the logic region is removed, and the memory cell layer in the memory array region is retained.

In some embodiments, the memory cell layer in the logic region is removed as follows:

the memory cell layer in the logic region is removed by both reactive ion etching and ion beam etching.

In some embodiments, the memory cell layer in the logic region is removed as follows: the memory cell layer in the logic region is removed by reactive ion etching or ion beam etching. In some embodiments, materials used in the bottom electrodes, the first portion of top contact body, the hard masks and the second portion of top contact body are tungsten or cobalt.

In some embodiments, the bottom electrodes of the memory array region and the first portion of top contact body of the logic region are formed on the upper surface of the bottom circuit layer simultaneously as follows:

the bottom electrodes and the first portion of top contact body are formed on the upper surface of the bottom circuit layer simultaneously by means of a chemical vapor deposition.

The present application further provides a memory. The memory is manufactured by any one of the above manufacturing methods for a memory.

### BRIEF DESCRIPTION OF THE DRAWINGS

In order to more clearly illustrate technical solutions in the examples of the present application or in the prior art, a brief introduction to the accompanying drawings required for the description of the examples or the prior art will be provided below. Apparently, the accompanying drawings in the following description are merely the examples of the present application, and those of ordinary skill in the art would also be able to derive other drawings from these provided drawings without making creative efforts.

FIG. 1 is a flowchart of a method for manufacturing a memory according to an example of the present application; and

FIGS. 2-15 are process flow diagrams of a method for manufacturing a memory according to an example of the present application.

### DETAILED DESCRIPTION OF THE EMBODIMENTS

In order to enable those skilled in the art to better understand the solutions of the present application, the present application is described in further detail below with reference to the accompanying drawings and particular embodiments. Apparently, the examples described are merely some examples rather than all examples of the present application. Based on the examples of the present application, all other examples obtained by those of ordinary skill in the art without making creative efforts fall within the scope of protection of the present application.

In the following description, numerous concrete details are set forth in order to provide a thorough understanding of the disclosure. However, the disclosure may be implemented otherwise than as specifically described herein. Those skilled in the art can make similar developments without departing from the spirit of the disclosure, and therefore the disclosure is not to be limited by the specific examples disclosed below.

As described in the background, currently, when forming the top contact body of a logic region, complicated processes, such as photography followed by etching and gap-filling are needed, which lead to a more costly fabrication approach.

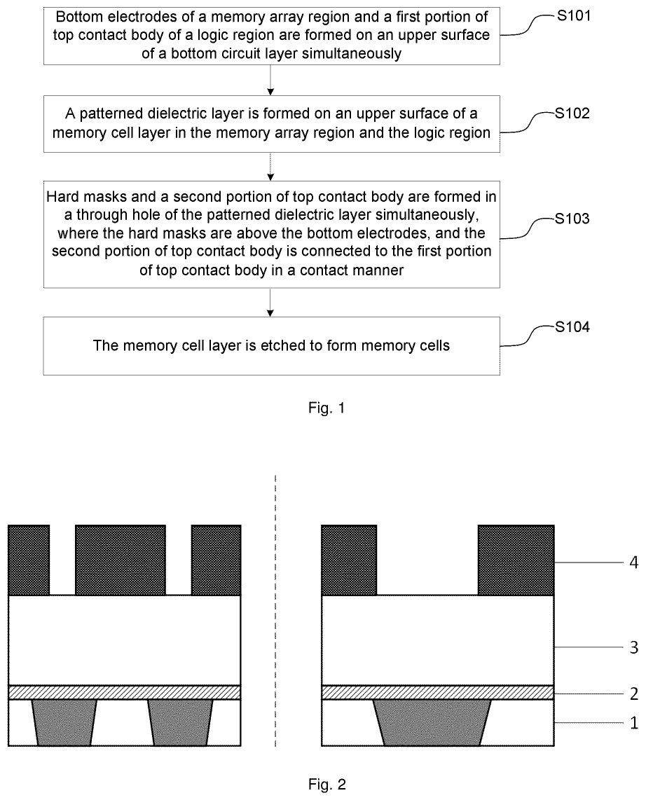

In view of this, the present application provides a method for manufacturing a memory. With reference to FIG. 1, the method for manufacturing a memory includes:

S101: bottom electrodes of a memory array region and a first portion of top contact body of a logic region are formed on an upper surface of a bottom circuit layer simultaneously.

A forming process of the bottom electrodes and the first portion of top contact body includes:

S1011: a silicon nitride barrier layer 2, a silicon oxide dielectric layer 3 and a photoresist layer are formed on the bottom circuit layer 1 of the memory array region and the logic region sequentially, and the photoresist is patterned to form a patterned photoresist layer 4, as shown in FIG. 2;

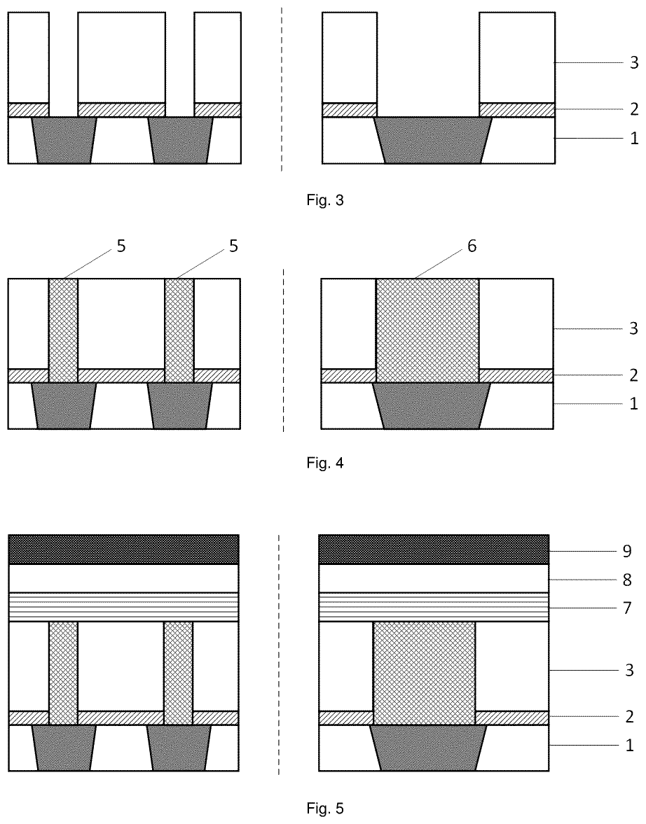

S1012: the silicon oxide dielectric layer 3 and the silicon nitride barrier layer 2 are etched with the patterned photoresist layer 4 as a mask to form vias of the bottom electrodes and the first portion of top contact via, followed by photoresist removal and cleaning, as shown in FIG. 3; and

S1013: the vias of the bottom electrodes and the first portion of top vias are filled with metal simultaneously followed by planarization to form the bottom electrodes 5 and the first portion of top contact body 6, as shown in FIG. 4. The planarization may use a chemical mechanical polishing mode.

It should be noted that materials of the bottom electrodes and the first portion of top contact body are not limited in the present application as long as they are conductive materials. For example, the bottom electrodes and the first portion of top contact body may be made of tantalum, tantalum nitride, tungsten or cobalt, etc. In some embodiments, the bottom electrodes and the first portion of top contact body are made of tungsten or cobalt, so as to reduce there-deposition caused in an etching process of the memory cell layer, improve a filling effect, and eliminate a risk of electron migration, thereby increasing product reliability.

In some embodiments, when the bottom electrodes and the first portion of top contact body are made of tungsten or cobalt, the bottom electrodes of the memory array region and the first portion of top contact body of the logic region are formed on the upper surface of the bottom circuit layer simultaneously as follows: the bottom electrodes and the first portion of top contact body are formed on the upper surface of the bottom circuit layer simultaneously through a chemical vapor deposition method.

Due to existence of the memory cell layers and the bottom electrodes in the memory array region, a depth of the top contact vias (a sum of depths of the first portion of top contact body and the second portion of top contact body) in the logic region is larger. Commonly used plating method cannot fulfill the requirement of high aspect ratio structure, which limits further increase the height of bottom electrodes and further shrink the size of top contact body. A chemical vapor deposition method can greatly reduce manufacturing difficulty when filling the top contact body of the logic region and further increase the height of the bottom electrodes.

S102. A patterned dielectric layer is formed on an upper surface of a memory cell layer in the memory array region and the logic region.

It should be pointed out that in an actual manufacturing process, in some embodiments, between S101 and S102, a forming process of the memory cell layer includes:

S201. The memory cell layer 7, a dielectric hard mask layer 8 and a photoresist layer 9 are sequentially stacked in the memory array region and the logic region, as shown in FIG. 5.

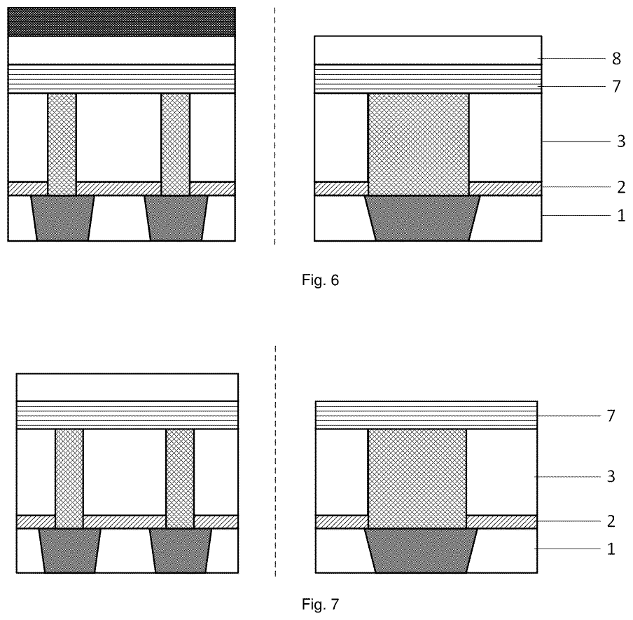

S202. The photoresist layer 9 in the logic region is removed, as shown in FIG. 6.

S203. The dielectric hard mask layer 8 in the logic region and the photoresist layer 9 in the memory array region are removed, as shown in FIG. 7.

In this step, reactive ion etching may be used to remove the dielectric hard mask layer.

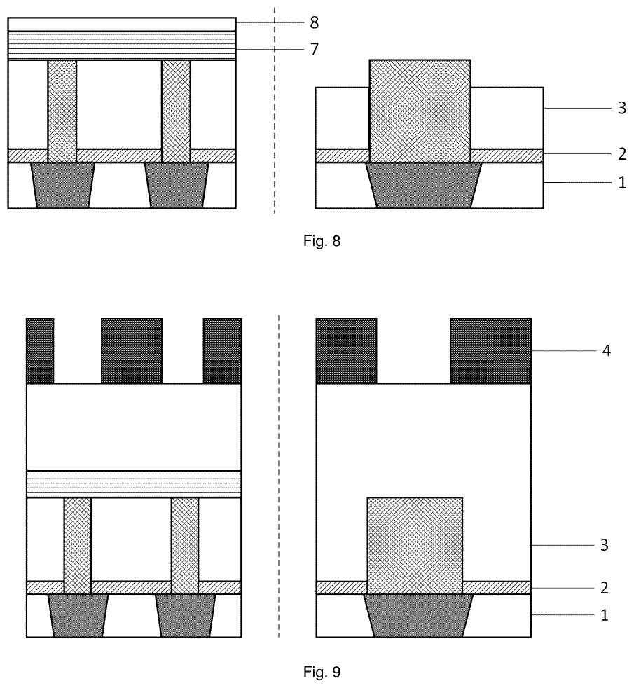

S204. The memory cell layer 7 in the logic region is removed, and the memory cell layer 7 in the memory array region is retained, as shown in FIG. 8.

In some embodiments, the memory cell layer in the logic region is removed as follows: the memory cell layer in the logic region is removed by both reactive ion etching and ion beam etching. However, this is not specifically limited in the present application. As another embodiment, the memory cell layer in the logic region may be removed by a reactive ion etching; and alternatively, the memory cell layer in the logic region may be removed by an ion beam etching.

It should be emphasized that in this step, to guarantee that the memory cell layer in the logic region is completely removed, the silicon oxide dielectric layer around the first portion of top contact body is partially etched, and a portion of the dielectric hard mask layer in the memory array region is also etched.

In the above process, a lower grade photomask can be used when the memory cell layer in the logic region is etched away, so as to further reduce a manufacturing cost.

The patterned dielectric layer is formed on an upper surface of a memory cell layer in the memory array region and the logic region as follows:

S1021. The silicon oxide dielectric material is backfilled followed by a chemical mechanical planarization to make sure that the same height of memory array and logic region. And the patterned photoresist layer 4 is formed on the silicon oxide dielectric layer, as shown in FIG. 9.

It should be pointed out that the mask used in this step and the mask used in S1011 may be a same mask, so as to reduce the manufacturing cost.

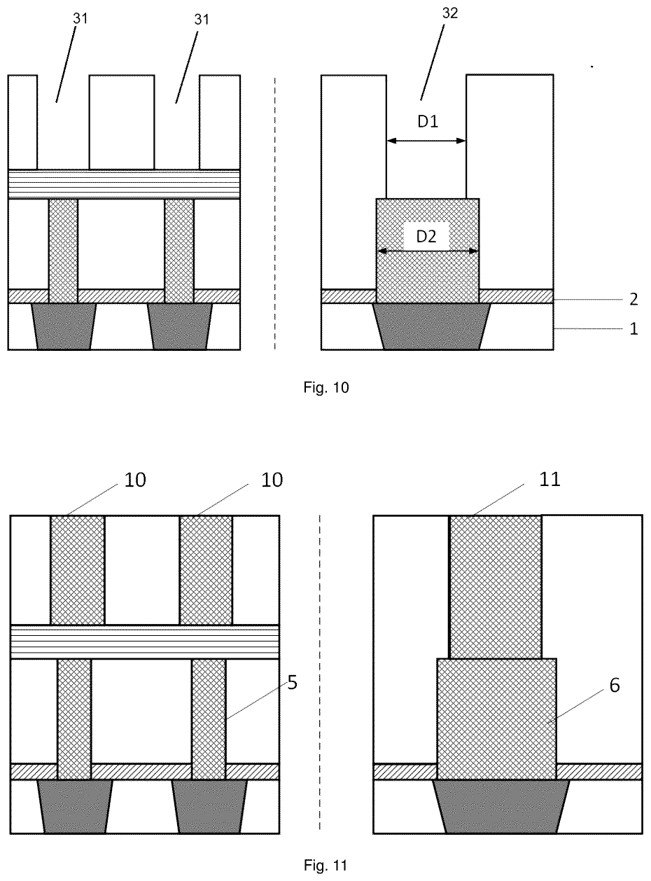

S1022. The patterned photoresist layer 4 is used as a mask, the silicon oxide dielectric layer 3 in the memory array region and the logic region is etched to form the patterned dielectric layer, followed by photoresist removal and cleaning, as shown in FIG. 10.

In some embodiments, a width D1 of the via corresponding to the second portion of top contact via is less than a width D2 of the first portion of top contact body when the dielectric layer patterning is formed, so as to control etching stop and avoid process variation cause by overlay.

S103: hard masks and a second portion of top contact body are formed in the patterned dielectric layer simultaneously, where the hard masks are above the bottom electrodes, and the second portion of top contact body is connected to the first portion of top contact body in a contact manner.

In this step, with reference to FIG. 11, after the hard masks 10 and the second portion of top contact body 11 are formed, a chemical mechanical planarization process is utilized.

It should be noted that materials of the hard masks and the second portion of top contact body are not limited in the present application as long as they are conductive materials. For example, the hard masks and the second portion of top contact body may be made of tantalum, tantalum nitride, tungsten or cobalt, etc. In some embodiments, the hard masks and the second portion of top contact body are made of tungsten or cobalt, so as to reduce re-deposition caused in an etching process of the memory cell layer, improve a filling effect, and eliminate a risk of electron migration, thereby increasing product reliability.

When the hard masks and the second portion of top contact body are made of tungsten or cobalt, the hard masks and the second portion of top contact body are simultaneously formed in the patterned dielectric layer as follows:

The hard masks and the second portion of top contact body are formed in the dielectric layer simultaneously by a chemical vapor deposition method.

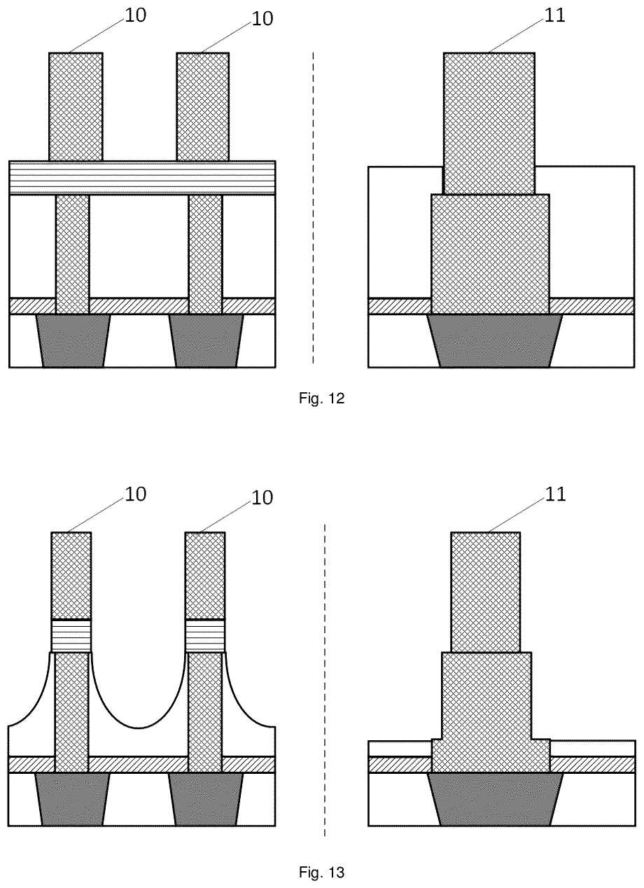

Further, after the hard masks and the second portion of top contact body are formed, the dielectric layer above the plane of the upper surface of the memory cell layer in the memory array region and the logic region should be removed, as shown in FIG. 12.

S104. The memory cell layer is etched to form memory cells.

When the memory cell layer is etched, the first portion of top contact body and the second portion of top contact body of the logic region are also etched, and the first portion of top contact body has an inverted T shape, as shown in FIG. 13.

In some embodiments, after the memory cell layer is etched to form the memory cells, the method for manufacturing a memory further includes:

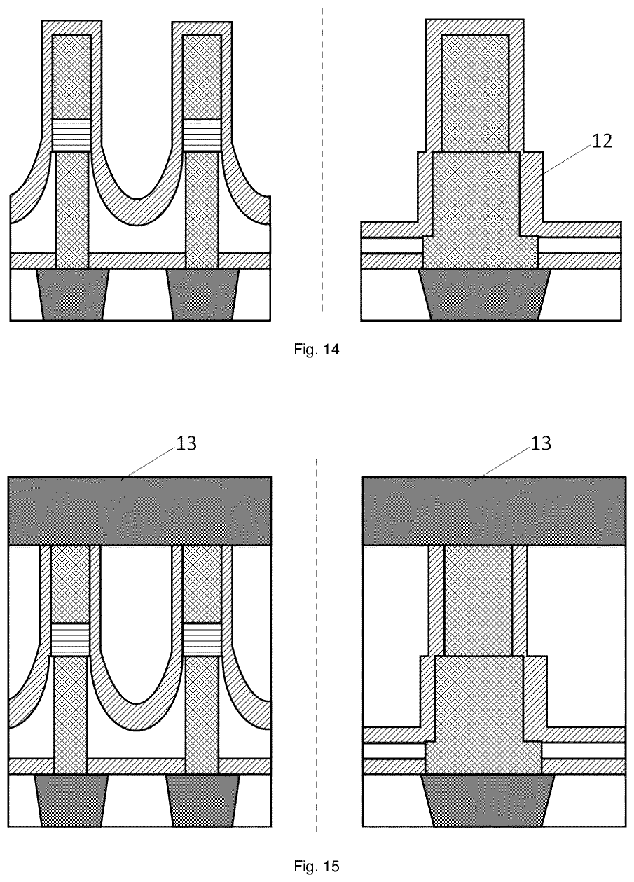

A protective layer 12 is deposited in the memory array region and the logic region, as shown in FIG. 14.

After the memory cell layers are formed or the protective layer is deposited, the dielectric materials are backfilled, in which a top circuit 13 is manufactured. A resulting memory is shown in FIG. 15.

When the memory is manufactured in the present application, the first portion of top contact body of the logic region and the bottom electrodes of the memory array region are formed simultaneously, the second portion of top contact body of the logic region and the hard masks of the memory array region are formed simultaneously, the second portion of top contact body is connected to the first portion of top contact body in a contact manner, and the first portion of top contact body and the second portion of top contact body form the top contact body of the logic region together, that is, a top contact body of the logic region is manufactured by two steps, and each of them are formed with a structure in the memory array region without separate photography and etch process to form via in the logic region, such that a manufacturing process is simplified.

In some embodiments, between the memory cell layer etching and the patterned dielectric layer above a plane of the upper surface of the memory cell layer removal from the memory array region and the logic region, the method for manufacturing a memory further includes:

a dielectric layer is deposited in the memory array region and the logic region, so as to reduce re-deposition in an etching process for the memory cell layer.

Materials of the dielectric layer include, but are not limited to, SiN, SiO2, SiON, etc.

The present application further provides a method for manufacturing the memory, wherein the memory has a memory array region and a logic region, and the method includes:
a bottom circuit layer 1, a silicon nitride dielectric layer 2 and a silicon oxide dielectric layer 3 are provided in a stacked manner, as shown in FIG. 2;
bottom electrodes 5 penetrating the dielectric layers 2 and 3 in the memory array region and extending to the bottom circuit layer 1 are formed, and a first portion of top contact body 6 penetrating the dielectric layers 2 and 3 in the logic region and extending to the bottom circuit layer 1 is formed, as shown in FIG. 4; the dielectric layer 2 and 3 may be silicon oxide dielectric layers.
a memory cell layer 7 covering the bottom electrodes 5 is formed, as shown in FIG. 5;
a patterned dielectric layer is formed over the bottom circuit layer 1, wherein the patterned dielectric layer has first via 31 and a second via 32, the first via 31 exposes the memory cell layer 7 and corresponds to the bottom electrodes 5, and the second via 32 exposes the first portion of top contact body 6, as shown in FIG. 10;
hard masks 10 filling the first vias 31 are formed, and a second portion of top contact body 11 filling the second via 32 is formed, as shown in FIG. 11; and
the memory cell layer 7 is etched to form memory cells according to the hard masks, as shown in FIG. 13.

In some embodiments, before the memory cell layer 7 is etched to form the memory cells, the method for manufacturing a memory further includes: the patterned dielectric layer above a plane of the upper surface of the memory cell layer 7 is removed from the memory array region and the logic region; a dielectric layer is deposited in the memory array region and the logic region, so as to reduce re-deposition in an etching process for the memory cell layer.

In some embodiments, a memory cell layer 7 is formed in the memory array region, a forming process of the memory cell layer 7 in the memory array region includes:

S201. The memory cell layer 7, a dielectric hard mask layer 8 and a photoresist layer 9 are sequentially stacked on a side of the bottom circuit layer 1 having the bottom electrodes 5 and the first portion of top contact body 6, as shown in FIG. 5.

S202. The photoresist layer 9 over the bottom circuit layer 1 in the logic region is removed, as shown in FIG. 6.

S203. The dielectric hard mask layer 8 located over the bottom circuit layer 1 in the logic region and the photoresist layer 9 located over the bottom circuit layer 1 in the memory array region are removed, as shown in FIG. 7.

In this step, when the dielectric hard mask layer 8 in the logic region is removed, reactive ion etching may be used to remove the dielectric hard mask layer 8.

S204. The memory cell layer 7 over the bottom circuit layer 1 in the logic region is removed, and the memory cell layer 7 over the bottom circuit layer 1 in the memory array region is retained, as shown in FIG. 8.

In some embodiments, a width D1 of the via corresponding to the second portion of top contact body (the first via 31) is less than a width D2 of the first portion of top contact body 6 when the patterned dielectric layer is formed, so as to control etching stop and avoid process variation cause by overlay, as shown in FIG. 10.

In some embodiments, after forming the memory cells, the method further includes: a protective layer 12 is deposited over the bottom circuit layer 1 in the memory array region and the logic region, as shown in FIG. 14.

In some embodiments, the memory cell layer over the bottom circuit layer in the logic region is removed as follows: the memory cell layer over the bottom circuit layer in the logic region is removed by both reactive ion etching and ion beam etching. However, this is not specifically limited in the present application. As another embodiment, the memory cell layer over the bottom circuit layer in the logic region may be removed by reactive ion etching only; and alternatively, the memory cell layer in the logic region may be removed by ion beam etching only.

In some embodiments, the bottom electrodes and the first portion of top contact body are made of tungsten or cobalt, so as to reduce re-deposition caused in an etching process of the memory cell layer improve a filling effect, and eliminate a risk of electron migration, thereby increasing product reliability.

In some embodiments, the hard masks and the second portion of top contact body may be made of tantalum, tantalum nitride, tungsten or cobalt, etc. In some embodiments, the hard masks and the second portion of top contact body are made of tungsten or cobalt, so as to reduce re-deposition caused in an etching process of the memory cell layer, improve a filling effect, and eliminate a risk of electron migration, thereby increasing product reliability.

In some embodiments, when the bottom electrodes and the first portion of top contact body are made of tungsten or cobalt, the bottom electrodes of the memory array region and the first portion of top contact body of the logic region are formed on the upper surface of the bottom circuit layer simultaneously as follows: the bottom electrodes and the first portion of top contact body are formed on the upper surface of the bottom circuit layer simultaneously by a chemical vapor deposition method.

The present application further provides a memory. The memory is manufactured by the method for manufacturing a memory in any one of the above examples.

Each example of the specification is described in a progressive manner, each example focuses on the difference from other examples, and reference may be made to each other for the same or similar parts between the examples. Since an apparatus disclosed in the examples corresponds to the method disclosed in the examples, the description is simple, and reference can be made to the description of the method.

The present application further provides a memory having a memory array region and a logic region, and the memory includes: a bottom circuit layer a silicon nitride dielectric layer and a silicon oxide dielectric layer in a stacked manner; bottom electrodes penetrating the dielectric layers in the array region and extending to the bottom circuit layer; a first portion of top contact body penetrating the dielectric layers in the logic region and extending to the bottom circuit layer; memory cell layers covering the bottom electrodes one by one; hard masks located one by one on a side of the memory cell layers facing away from the bottom circuit layer, wherein projections of the hard masks over the bottom circuit layer coincides with projections of the memory cell layers on the bottom circuit layer; and a second portion of top contact body located on a side of the first portion of top contact body facing away from the bottom circuit layer, wherein a projection of the second portion of top contact body over the bottom circuit layer is located in a projection of the first portion of top contact body on the bottom circuit layer.

In some embodiments, the bottom electrodes and the first portion of top contact body are made of tungsten or cobalt, so as to reduce re-deposition caused in an etching process of the memory cell layer, improve a filling effect, and eliminate a risk of electron migration, thereby increasing product reliability.

In some embodiments, the hard masks and the second portion of top contact body may be made of tantalum, tantalum nitride, tungsten or cobalt, etc. In some embodiments, the hard masks and the second portion of top contact body are made of tungsten or cobalt, so as to reduce re-deposition caused in an etching process of the memory cell layer, improve a filling effect, and eliminate a risk of electron migration, thereby increasing product reliability.

The memory and the method for manufacturing thereof provided in the present application are described in detail above. A principle and embodiments of the present application are described by applying particular instances, and the description of the above examples is only configured to help to understand the method and the core idea of the present application. It should be noted that several improvements and modifications can be made by those of ordinary skill in the art without departing from the principles of the present application, which should also be considered to fall within the scope of protection of the present application.

1. A method for manufacturing a memory, comprising:
forming bottom electrodes of a memory array region and a first portion of top contact body of a logic region on an upper surface of a bottom circuit layer simultaneously;
forming a patterned dielectric layer on an upper surface of a memory cell layer in the memory array region and the logic region;
forming hard masks and a second portion of top contact body in vias of the patterned dielectric layer simultaneously, and the second portion of top contact body is connected to the first portion of top contact body in a contact manner; and
etching the memory cell layer to form memory cells, and obtaining the memory.

2. The method for manufacturing the memory according to claim 1, wherein before etching the memory cell layer to form the memory cells, the method for manufacturing a memory further comprises:
removing the patterned dielectric layer above a plane of the upper surface of the memory cell layer from the memory array region and the logic region;
depositing a dielectric layer in the memory array region and the logic region.

3. The method for manufacturing the memory according to claim 1, wherein a width of the via corresponding to the second portion of top contact body is less than a width of the first portion of top contact body when the patterned dielectric layer is formed.

4. The method for manufacturing the memory according to claim 1, wherein after etching the memory cell layer to form the memory cells, the method for manufacturing a memory further comprises:
depositing a protective layer in the memory array region and the logic region.

5. The method for manufacturing the memory according to claim 1, wherein a forming process of the memory cell layer in the memory array region comprises:
forming the memory cell layer, a dielectric hard mask layer and a photoresist layer sequential stack in the memory array region and the logic region;
removing the photoresist layer in the logic region;
removing the dielectric hard mask layer in the logic region and the photoresist layer in the memory array region; and
removing the memory cell layer in the logic region, and retaining the memory cell layer in the memory array region.

6. The method for manufacturing the memory according to claim 5, wherein removing the memory cell layer in the logic region comprises:
removing the memory cell layer to be processed in the logic region by both reactive ion etching and ion beam etching.

7. The method for manufacturing the memory according to claim 5, wherein removing the memory cell layer in the logic region comprises:
removing the memory cell layer to be processed in the logic region by reactive ion etching or ion beam etching.

8. The method for manufacturing the memory according to claim 1, wherein the bottom electrodes, the first portion of top contact body, the hard masks and the second portion of top contact body are made of tungsten or cobalt.

9. (canceled)

10. A memory, manufactured by the method for manufacturing the memory according to claim 1.

11. A method for manufacturing the memory, wherein the memory has a memory array region and a logic region, and the method comprises:
providing a bottom circuit layer and a silicon oxide dielectric layer arranged in a stacked manner;
forming bottom electrodes penetrating the silicon oxide dielectric layer in the memory array region and extending to the bottom circuit layer, and forming a first portion of top contact body penetrating the silicon oxide dielectric layer in the logic region and extending to the bottom circuit layer;
forming a memory cell layer covering the bottom electrodes;
forming a patterned dielectric layer over the bottom circuit layer, wherein the patterned dielectric layer has first vias and second vias, the first vias exposes the memory cell layer and the second vias expose the first portion of top contact body;
forming hard masks filling the first vias, and forming a second portion of top contact body filling the second vias; and
etching the memory cell layer to form memory cells according to the hard masks.

12. The method for manufacturing the memory according to claim 11, wherein before forming memory cells, the method further comprises:
removing the patterned dielectric layer above a plane of the upper surface of the memory cell layer from the memory array region and the logic region; and
depositing a dielectric layer over the bottom circuit layer in the memory array region and the logic region.

13. The method for manufacturing the memory according to claim 11, wherein a width of the vias corresponding to the second portion of top contact body is less than a width of the first portion of top contact body when the patterned dielectric layer is formed.

14. The method for manufacturing the memory according to claim 11, wherein after forming the memory cells, the method further comprises:
depositing a protective layer over the bottom circuit layer in the memory array region and the logic region.

15. The method for manufacturing the memory according to claim 11, wherein a forming process of the memory cell layer in the memory array region comprises:
forming the memory cell layer, a dielectric hard mask layer and a photoresist layer sequential stack on a side of the bottom circuit layer having the bottom electrodes and the first portion of top contact body;
removing the photoresist layer located over the bottom circuit layer in the logic region;
removing the dielectric hard mask layer located over the bottom circuit layer in the logic region and the photoresist layer located over the bottom circuit layer in the memory array region; and
removing the memory cell layer over the bottom circuit layer in the logic region, and retaining the memory cell layer over the bottom circuit layer in the memory array region.

16. The method for manufacturing the memory according to claim 15, wherein removing the memory cell layer over the bottom circuit layer in the logic region comprises:
removing the memory cell layer over the bottom circuit layer in the logic region by both reactive ion etching and ion beam etching.

17. The method for manufacturing the memory according to claim 15, wherein removing the memory cell layer over the bottom circuit layer in the logic region comprises:
removing the memory cell layer over the bottom circuit layer in the logic region by reactive ion etching or ion beam etching.

18. The method for manufacturing the memory according to claim 11, wherein the bottom electrodes, the first portion of top contact body, the hard masks and the second portion of top contact body are made of tungsten or cobalt.

19. The method for manufacturing the memory according to claim 18, wherein forming the bottom electrodes and forming the first portion of top contact body comprises:
forming the bottom electrodes and the first portion of top contact body on the upper surface of the bottom circuit layer simultaneously by a chemical vapor deposition method.

20. A memory, having a memory array region and a logic region, and comprising:
a bottom circuit layer and a silicon oxide dielectric layer arranged in a stacked manner;
bottom electrodes penetrating the silicon oxide dielectric layer in the array region and extending to the bottom circuit layer;
a first portion of top contact body penetrating the silicon oxide dielectric layer in the logic region and extending to the bottom circuit layer;
memory cell layers covering the bottom electrodes one by one;
hard masks located one by one on a side of the memory cells facing away from the bottom circuit layer, wherein projections of the hard masks over the bottom circuit layer coincides with projections of the memory cells on the bottom circuit layer; and
a second portion of top contact body located on a side of the first portion of top contact body facing away from the bottom circuit layer, wherein a projection of the second portion of top contact body over the bottom circuit layer is located in a projection of the first portion of top contact body on the bottom circuit layer.

21. The memory according to claim 20, wherein the bottom electrodes, the first portion of top contact body, the hard masks and the second portion of top contact body are made of tungsten or cobalt.
